(19) United States
(12) Patent Application Publication
(10) Pub. No.: US 2025/0048802 A1
(43) Pub. Date: Feb. 6, 2025

(54) LIGHT-EMITTING DEVICE AND LIGHT SOURCE DEVICE

(71) Applicant: NICHIA CORPORATION, Anan-shi, (JP)

(72) Inventors: Shunsuke ASHIDA, Anan-shi (JP); Atsushi BANDO, Itano-gun (JP)

(73) Assignee: NICHIA CORPORATION, Anan-shi (JP)

(21) Appl. No.: 18/705,336

(22) PCT Filed: Oct. 20, 2022
(86) PCT No.: PCT/JP2022/039106

§ 371 Date: Apr. 26, 2024

(30) Foreign Application Priority Data
Oct. 28, 2021 (JP) 2021176587
Dec. 14, 2021 (JP) 2021202482

(51) Int. Cl. H01L 33/50

(52) U.S. Cl. CPC H01L 33/504

(57) ABSTRACT

Provided is a light-emitting device capable of improving discernibility of letters or the like when used by a person with reduced visual sensitivity to blue light. The light-emitting device comprises a light-emitting element emitting light having an emission peak wavelength in a range of 440 nm to 470 nm, and a wavelength conversion member including a plurality of phosphors emitting light when excited by the light from the light emitting element. Ratios of luminous intensities of the light emitted from the light emitting device at wavelengths 480 nm, 530 nm, and 550 nm to the luminous intensity at the peak emission wavelength attributed to the light emitting element in an emission spectrum are 0.05 to 0.20, 0.20 to 0.35, and 0.23 to 0.38, respectively.

### TECHNICAL FIELD

The present disclosure relates to a light emitting device and a light source device.

### BACKGROUND ART

As a light emitting device emitting white light by using a light emitting diode (hereinafter also referred to as “LED”), there is one that combines a blue light emitting LED and a yellow light emitting phosphor. This light emitting device emits white light resulting from mixing blue light from the LED and yellow light from the phosphor that is excited by the blue light. In general, the light from a white light emitting device has a color positioned on the blackbody radiation locus.

With respect to the color of the light emitted from a light emitting device, for example, a light emitting device capable of improving the perceived discernibility of displayed letters has been proposed (e.g., Japanese Patent Publication No. 2018-088374).

### SUMMARY OF INVENTION

### Technical Problem

In the elderly, the discoloration of the crystalline lens caused by aging is known to reduce the visual sensitivity to light of a short wavelength such as blue light. When the visual sensitivity to light of a short wavelength side is reduced, an object appears yellowish which tends to reduce the discernability of displayed letters or the like. An object of one aspect of the present disclosure is to provide a light emitting device capable of improving the discernability of letters or the like when used by a person with reduced visual sensitivity to blue light.

A first aspect of the disclosure is a light emitting device that includes a light emitting element emitting light having a peak emission wavelength in a range of 440 nm to 470 nm and a wavelength conversion member including multiple phosphors emitting light when excited by the light from the light emitting element. In the light emitting device, ratios of luminous intensities at wavelengths 480 nm, 530 nm, and 550 nm in the emission spectrum to the luminous intensity at the peak emission wavelength attributed to the light emitting element are 0.05 to 0.20, 0.20 to 0.35, and 0.23 to 0.38, respectively.

A second aspect is a light source device that includes the light emitting device of the first aspect including a first light emitting device emitting light of a correlated color temperature in a range of 7000 K to 9200 K and a second light emitting device emitting light of a correlated color temperature in a range of 2600 K to 2900 K, and a color of light emitted from the light source device is adjustable in a correlated color temperature range of 2600 K to 9200 K.

### Advantageous Effects of Invention

According to one aspect of the present disclosure, a light emitting device capable of improving the discernibility of letters or the like when used by a person with reduced visual sensitivity to blue light can be provided.

### BRIEF DESCRIPTION OF DRAWINGS

FIG. 1 is a schematic cross-sectional view of an example of a light emitting device according to an embodiment.

FIG. 2 is a diagram showing the emission spectra of the light emitting devices in the Examples and the Comparative Examples.

FIG. 3 is a diagram showing the chromaticity coordinates of the emission colors of the light emitting devices in the Examples and the Comparative Examples.

FIG. 4 is a diagram showing the aging-induced changes in the chromaticity coordinates of the emission colors of the light emitting devices in the Examples and the Comparative Examples.

### DESCRIPTION OF EMBODIMENTS

In the present specification, the term “process” includes not only an independent process, but also one that can achieve the intended objective of a process even if not clearly distinguishable from another process. The content of each component in a composition in the case where multiple pieces of a substance make up a component in the composition means the total amount of the substance present in the composition unless otherwise stated. With respect to the upper limits and the lower limits of numerical value ranges described in the present specification, the numerical values provided as examples in the form of numerical value ranges can be freely selected to be combined. In the present specification, the relationship between a color name and the chromaticity coordinates, the relationship between a wavelength range of light and the color name of a monochromatic color, and the like are in accordance with JIS Z 8110. The half-value width of a phosphor means the width of the emission spectrum curve at which the luminous intensity is 50% of the maximum luminous intensity, i.e., the full width at half maximum (FWHM). In the present specification, moreover, the multiple elements in a formula representing the composition of a phosphor or light emitting material separated by a comma (,) mean that at least one of the elements is contained in the composition. Furthermore, in a formula representing the composition of a phosphor, what comes before the colon (:) represents the host crystal and what follows the colon represents the activating element. Certain embodiments of the present disclosure will be described in detail below. However, the embodiments described below are examples of light emitting devices and light source devices provided for the purpose of giving shape to the technical ideas of the present disclosure. As such, the present disclosure is not limited to the light emitting devices and the light source devices described below.

### Light Emitting Device

A light emitting device includes a light emitting element emitting light having a peak emission wavelength in a range of 440 nm to 470 nm and a wavelength conversion member including multiple phosphors emitting light when excited by the light from the light emitting element. The ratio of the luminous intensity of the light from the light emitting device at wavelength 480 nm in the emission spectrum to the luminous intensity of the emission peak attributed to the light emitting element at the peak emission wavelength (the maximum luminous intensity) may be 0.05 to 0.20. The ratio of the luminous intensity at wavelength 480 nm may preferably be 0.10 or higher, 0.12 or higher, 0.15 or higher, 0.16 or higher, 0.17 or higher, or 0.175 or higher, and preferably 0.19 or lower, or 0.185 or lower.

The ratio of the luminous intensity of the light from the light emitting device at wavelength 530 nm in the emission spectrum to the luminous intensity of the emission peak attributed to the light emitting element at the peak emission wavelength may be 0.20 to 0.35. The ratio of the luminous intensity at wavelength 530 nm may preferably be 0.24 or higher, 0.27 or higher, 0.28 or higher, or 0.29 or higher, and preferably 0.34 or lower, 0.33 or lower, or 0.32 or lower.

The ratio of the luminous intensity of the light from the light emitting device at wavelength 550 nm in the emission spectrum to the luminous intensity of the emission peak attributed to the light emitting element at the peak emission wavelength may be 0.23 to 0.38. The ratio of the luminous intensity at wavelength 550 nm may preferably be 0.24 or higher, 0.25 or higher, 0.26 or higher, 0.27 or higher, 0.28 or higher, 0.29 or higher, or 0.30 or higher, and preferably 0.36 or lower, 0.34 or lower, or 0.33 or lower.

Setting the ratios of the luminous intensity at wavelengths 480 nm, 530 nm, and 550 nm to the maximum luminous intensity of the emission peak attributed to the light emitting element to the ranges described above can reduce the yellow component of the light emitted from the light emitting device, thereby relatively increasing the blue component. This, as a result, can allow a person with reduced visual sensitivity to blue light to visually recognize an object irradiated by the light from the light emitting device of the present disclosure as if the object is irradiated by the light having chromaticity coordinates in the vicinity of the blackbody radiation locus based on the visible spectrum estimated for the person.

Here, the chromaticity coordinates of light calculated based on the visible spectrum estimated for a subject person can be calculated as described below, for example. The emission spectrum of a light emitting device is measured, and the measured spectrum is converted into the emission spectrum based on the visible spectrum for the person. Then the chromaticity coordinates are calculated from the converted emission spectrum. In this manner, the chromaticity coordinates of the light estimated to be recognized by the person are calculated.

The emission spectrum of the light emitting device based on the visible spectrum estimated for the person can be calculated by multiplying the transmittance of the crystalline lens corresponding to the age of the person by the emission spectrum of the light emitting device. The transmittance of the crystalline lens corresponding to the age of the person is described in CIE TECHNICAL REPORT, CIE203: 2012 Incl. Erratum 1, for example, as the estimated transmittance every 5 nm in a wavelength range of 300 nm to 700 nm for each age. Specifically, the emission spectrum estimated to be recognized by the person can be obtained by dividing the estimated transmittance of the person at his age for each wavelength by the estimated transmittance of a person of the age expected to have a standard visible spectrum (e.g., a 20-year old), followed by multiplying the value thus obtained by the luminous intensity at the wavelength in the emission spectrum of the light emitting device. The chromaticity coordinates of the light from the light emitting device estimated to be recognized by the person can be calculated from the emission spectrum thus obtained. For example, the chromaticity coordinates calculated from the emission spectrum of the light emitting device can be calculated by using a usual method based on the tristimulus values extracted from that emission spectrum. The conversion from the emission spectrum into the chromaticity coordinates can be accomplished by the conversion method defined in CIE 1931.

A light emitting device in which the ratios of luminous intensity at wavelengths 480 nm, 530 nm, and 550 nm to the luminous intensity of the emission peak attributed to the light emitting element at the peak emission wavelength fall within the respective specific ranges can improve the discernability of letters or the like when used by a person with reduced visual sensitivity to blue light. Furthermore, when used by an elderly person, for example, the light emitting device of the present disclosure can improve the discernability of the color of the object observed.

In one aspect, the light emitted from the light emitting device may has the correlated color temperature of 6000 K or higher, but lower than 7000 K. The correlated color temperature of the light emitted from the light emitting device may preferably be 6100 K or higher or 6300 K or higher, and preferably 6900 K or lower, 6700 K or lower, 6500 or lower, or 6400 K or lower.

In the case in which the correlated color temperature of the light emitted from the light emitting device is 6000 K or higher, but lower than 7000 K, the chromaticity coordinates of the light emitted from the light emitting device may fall within the area of the CIE 1931 chromaticity diagram enclosed by four straight lines connecting the first point (x=0.322 and y=0.326), the second point (x=0.307 and y=0.312), the third point (x=0.310 and y=0.294), and the fourth point (x=0.324 and y=0.305), the first line connecting the fourth point and the first point, the second line connecting the first point and the second point, the third line connecting the second point and the third point, and the fourth line connecting the third point and the fourth point. In other words, the chromaticity coordinates of the light emitted from the light emitting device may fall within the quadrilateral having the first, second, third, and fourth points as its vertices. Having the chromaticity coordinates of the light emitted from the light emitting device in this area can allow a person with reduced visual sensitivity to blue light to visually recognize an object irradiated by the light from the light emitting device of the present disclosure as if the object is irradiated by the light having chromaticity coordinates in the vicinity of the blackbody radiation locus based on the visible spectrum estimated for the person.

In the case in which the correlated color temperature of the light emitted from the light emitting device is 6000 K or higher, but lower than 7000 K, the light emitted from the light emitting device may have a color deviation duv from the blackbody radiation locus in the range of −0.015 to −0.001 in the CIE 1931 chromaticity diagram. The color deviation duv may preferably be −0.012 or higher, −0.011 or higher, or −0.010 or higher, and preferably −0.003 or lower, −0.006 or lower, −0.008 or lower, or −0.009 or lower. Setting the color deviation duv in the above range can allow a person with reduced visual sensitivity to blue light to visually recognize an object irradiated by the light from the light emitting device of the present disclosure as if the object is irradiated by the light having chromaticity coordinates in the vicinity of the blackbody radiation locus based on the visible spectrum estimated for the person.

In one aspect of the disclosure, the correlated color temperature of the light emitted from the light emitting device may be 7000 K to 9200 K. The correlated color temperature of the light emitted from the light emitting device may preferably be 7200 K or higher, 7500 K or higher, 7600 K or higher, or 7800 K or higher, and preferably 9000 K or lower, 8500 K or lower, 8000 K or lower, or 7900 K or lower.

In the case in which the correlated color temperature of the light emitted from the light emitting device is in the range of 7000 K to 9200 K, the chromaticity coordinates of the light emitted from the light emitting device may fall within the area of the CIE 1931 chromaticity diagram enclosed by four straight lines connecting the fifth point (x=0.292 and y=0.280), the sixth point (x=0.287 and y=0.292), the seventh point (x=0.307 and y=0.312), and the eighth point (x=0.310 and y=0.294), the fifth line connecting the eighth point and the fifth point, the sixth line connecting the fifth point and the sixth point, the seventh line connecting the sixth point and the seventh point, and the eighth line connecting the seventh point and the eighth point. In other words, the chromaticity coordinates of the light emitted from the light emitting device may fall within the quadrilateral having the fifth, sixth, seventh, and eighth points as its vertices. Having the chromaticity coordinates of the light emitted from the light emitting device to in this range can allow a person with reduced visual sensitivity to blue light to visually recognize an object irradiated by the light from the light emitting device of the present disclosure as if it is irradiated by the light having chromaticity coordinates in the vicinity of the blackbody radiation locus based on visible spectrum estimated for the subject person.

In the case in which the correlated color temperature of the light emitted from the light emitting device is in the range of 7000 K to 9200 K, the light emitted from the light emitting device may have a color deviation duv from the blackbody radiation locus in the range of −0.015 to −0.001 in the CIE 1931 chromaticity diagram. The color deviation duv may preferably be −0.012 or higher, −0.010 or higher, −0.009 or higher, or −0.008 or higher, and preferably −0.002 or lower, −0.004 or lower, −0.006 or lower, or −0.007 or lower. Setting the color deviation duv in the above range can allow a person with reduced visual sensitivity to blue light to visually recognize an object irradiated by the light from the light emitting device of the present disclosure as if it is irradiated by the light having chromaticity coordinates in the vicinity of the blackbody radiation locus based on the visible spectrum estimated for the subject person.

The emission spectrum of the light emitting device may be such that the ratio of the luminous intensity at wavelength 500 nm to the luminous intensity of the emission peak attributed to the light emitting element at the peak emission wavelength can be 0.20 to 0.35, for example. The ratio of the luminous intensity at wavelength 500 nm may preferably be 0.21 or higher, 0.22 or higher, or 0.23 or higher, and preferably 0.32 or lower, 0.30 or lower, 0.28 or lower, 0.26 or lower, or 0.24 or lower. This can reduce the yellow component of the light emitted from the light emitting device, relatively increasing the blue component. This, as a result, can allow a person with reduced visual sensitivity to blue light to visually recognize an object irradiated by the light from the light emitting device of the present disclosure as if the object is irradiated by light having chromaticity coordinates in the vicinity of the blackbody radiation locus based on the visible spectrum estimated for the person.

The emission spectrum of the light emitting device may be such that the ratio of the luminous intensity at wavelength 580 nm to the luminous intensity of the emission peak attributed to the light emitting element at the peak emission wavelength can be 0.20 to 0.35, for example. The ratio of the luminous intensity at wavelength 580 nm may preferably be 0.25 or higher. 0.26 or higher. 0.27 or higher, 0.28 or higher, or 0.30 or higher, and preferably 0.345 or lower, 0.34 or lower, or 0.33 or lower. This can reduce the yellow component of the light emitted from the light emitting device, relatively increasing the blue component. This, as a result, allows a person with reduced visual sensitivity to blue light to visually recognize an object irradiated by the light from the light emitting device of the present disclosure as if the object is irradiated by light having chromaticity coordinates in the vicinity of the blackbody radiation locus based on the visible spectrum estimated for the person.

The emission spectrum of the light emitting device may have an emission peak in the range of 620 nm to 650 nm, for example. Here, having an emission peak in the range of 620 nm to 650 nm means that the emission spectrum of the light emitting device has at least one maximum luminous intensity value in the range of 620 nm to 650 nm range. The wavelength range in which the emission spectrum of the light emitting device has a peak emission wavelength may preferably be 625 nm or higher, and 640 nm or lower.

In the case in which the emission spectrum of the light emitting device has an emission peak in the range of 620 nm to 650 nm, the half-value width of the emission peak may be 15 nm or lower. The half-value width of the emission peak may be 10 nm or lower, or 8 nm or lower. The lower limit of the half-value width of the emission peak may be 3 nm or higher, for example. By having a narrow half-width emission peak in the range of 620 nm to 650 nm, it is possible to be the light emitting device that emits light with high color rendering and high efficiency.

The light emitted from the light emitting device may have predetermined color rendering characteristics. The color rendering of the light emitting device can be assessed by using a color rendering index. The color rendering index is arithmetically calculated based on the color differences ΔEi (i is an integer from 1 to 15) obtained by measuring test colors (R1 to R15) having predetermined reflectance with a test light source and a reference light source in accordance with JIS Z 8726. The upper limit of a color rendering index Ri (i is an integer from 1 to 15) is 100. In other words, the smaller the color differences between the test light source and the reference light source having the corresponding color temperature, the higher and closer to 100 the color rendering index becomes. The average value of R1 to R8 among color rendering indices is referred to as the average color rendering index (hereinafter occasionally referred to as Ra), and R9 to R15 are referred to as special color rendering indices. With respect to the special color rendering indices, for example, R9 corresponds to red.

The average color rendering index Ra of the light emitting device may be, for example, 70 to 100. The average color rendering index Ra of the light emitting device may preferably be 80 or higher, 90 or higher, or 92 or higher, and 98 or lower, 95 or lower, or 94 or lower. In the case in which the correlated color temperature of the light emitted from the light emitting device is 6000 K or higher, but lower than 7000 K, the special color rendering index R9 of the light emitting device may be, for example, 70 to 100, preferably 80 or higher, 85 or higher, or 88 or higher, and 95 or lower, or 92 or lower. In the case in which the correlated color temperature of the light emitted from the light emitting device is 7000 K to 9200 K, the special color rendering index R9 of the light emitting device may be, for example, 70 to 100, preferably 80 or higher, 85 or higher, or 86 or higher, and 90 or lower, or 88 or lower. Setting the color rendering indices of the light emitting device in these ranges can allow the light emitting device to emit white light that is close to natural light.

The light emitting device having the emission spectrum described above is configured by including, for example, a light emitting element emitting light having a peak emission wavelength in a range of 440 nm to 470 nm and a wavelength conversion member containing multiple phosphors which emit light when excited by the light from the light emitting element. The wavelength conversion member may include, for example, a first phosphor emitting light having a peak emission wavelength in the range of 520 nm to 545 nm, a second phosphor emitting light having a peak emission wavelength in the range of 605 nm to 670 nm, and a third phosphor emitting light having a peak emission wavelength in the range of 610 nm to 650 nm. The wavelength conversion member may include, for example, a first phosphor emitting light having a peak emission wavelength in the range of 520 nm to 545 nm, a second phosphor emitting light having a peak emission wavelength in the range of 605 nm to 670 nm, and a fourth phosphor containing a halogen and emitting light having a peak emission wavelength in the range of 505 nm to 530 nm.

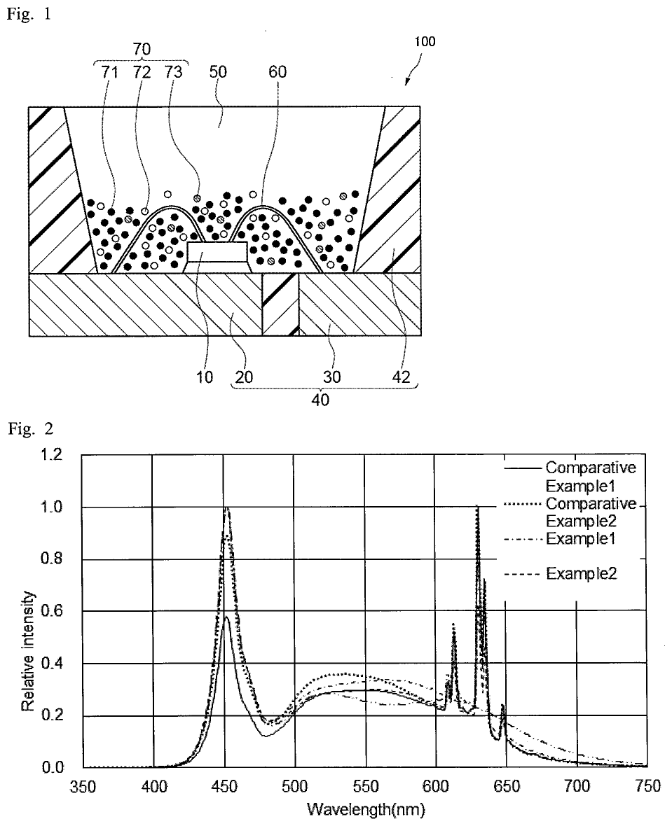

Here, an example of the light emitting device will be explained with reference to a drawing. FIG. 1 is a schematic cross-sectional view of the light emitting device. The light emitting device 100 includes a light emitting element 10 emitting light having a peak emission wavelength in a range of 440 nm to 470 nm, and a wavelength conversion member 50. The wavelength conversion member 50 includes, for example, at least three types of phosphors 70: a first phosphor 71 emitting light having a peak emission wavelength in the range of 520 nm to 545 nm, a second phosphor 72 emitting light having a peak emission wavelength in the range of 605 nm to 670 nm, and a third phosphor 73 emitting light having a peak emission wavelength in the range of 610 nm to 650 nm.

The light emitting device 100 emits visible light on the short wavelength side (e.g., in the 380 nm to 485 nm range), and has a light emitting element 10 formed of a gallium nitride-based compound semiconductor and emitting light having a peak emission wavelength in a range of 440 nm to 470 nm, and a formed body 40 on which the light emitting element 10 is mounted. The formed body 40 is formed of a first lead 20, a second lead 30, and a resin part 42 which are monolithically formed. Alternatively, the formed body 40 can be formed with a ceramic material in place of the resin part 42 by using a known method. The formed body 40 has a recessed shape having a bottom face and a lateral face. The light emitting element 10 is placed on the bottom face of the recess. The light emitting element 10 has a pair of positive and negative electrodes, and the positive and negative electrodes are respectively electrically connected to the first lead 20 and the second lead 30 via wires 60. The light emitting element 10 is covered by the wavelength conversion member 50. The wavelength conversion member 50 is formed of a resin and at least three types of phosphors 70 that convert the wavelength of the light from the light emitting element 10, including a first phosphor 71, a second phosphor 72, and a third phosphor 73, for example.

### Light Emitting Element

The peak emission wavelength of the light from the light emitting element is in a range of 440 nm to 470 nm, preferably in the range of 445 nm to 460 nm from the luminescence efficiency standpoint. Using a light emitting element having a peak emission wavelength in this range as an excitation light source can configure a light emitting device that emits mixed color light in which the light from the light emitting element and the fluorescent light from the phosphors are combined. Moreover, the light emitted from the light emitting element can be utilized efficiently. This can reduce loss of light from the light emitting device, making it a highly efficient light emitting device. Furthermore, the peak emission wavelength is on the longer wavelength side than the near ultraviolet region, i.e., the ultraviolet component is limited. This makes the light emitting element a highly safe and highly efficient light source.

The half-value width of the emission spectrum of the light emitting element can be set, for example, to 30 nm or lower. For the light emitting element, a semiconductor light emitting element such as an LED is preferably used. Using a semiconductor light emitting element as a light source can produce a high efficiency, high input-output linearity, high mechanical shock resistant, and stable light emitting device. For the semiconductor light emitting element, for example, a semiconductor light emitting element employing a nitride based semiconductor (In_{X}Al_{Y}Gan_{X-Y}N, where X and Y satisfy 0≤X, 0≤Y, and X+Y<1) and emitting blue light, green light, or the like can be used.

### Wavelength Conversion Member

The wavelength conversion member can include, for example, a phosphor and a resin. The wavelength conversion member may include as phosphors at least one first phosphor that absorbs the light from the light emitting element and emits green light, at least one second phosphor that emits red light, and at least one third phosphor that emits deep red light. The first to third phosphors have compositions different from one another. Suitably selecting the composition ratio of the first to third phosphors can have desired ranges of luminescence efficiency of the light emitting device and of the properties, such as the chromaticity coordinates of the emitted light. In the case in which the wavelength conversion member includes the first to third phosphors, the correlated color temperature of the light emitted from light emitting device may be, for example, 6000 K to 9200 K.

The wavelength conversion member may include as phosphors at least one first phosphor that absorbs the light from the light emitting element and emits green light, at least one second phosphor that emits red light, and at least one fourth phosphor that emits green light. The first, second, and fourth phosphors have compositions different from one another. Suitably selecting the composition ratio of the first, second, and fourth phosphors can have desired ranges of luminescence efficiency of the light emitting device and the properties, such as the chromaticity coordinates of the emitted light. In the case in which the wavelength conversion member includes the first, second, and fourth phosphors, the correlated color temperature of the light emitted from light emitting device may be, for example, 7000 K to 9200 K.

Examples of the resin that makes up the wavelength conversion member include silicone resins, epoxy resins, modified silicone resins, modified epoxy resins, acrylic resins, and the like. For example, the refractive index of a silicone resin may be in the range of 1.35 to 1.55, more preferably in the range of 1.38 to 1.43. A silicone resin having a refractive index in these ranges is highly light transmissive and can be suitably used as the resin that composes a fluorescent member. The refractive index of a silicone resin here is that measured after the resin is hardened and is measured in accordance with JIS K 7142: 2008. The wavelength conversion member may further include a light diffusing material in addition to the resin and phosphors. Including a light diffusing material can lessen the directivity of the light from the light emitting element, widening the viewing angle. Examples of the light diffusing material include silicon oxide, titanium oxide, zinc oxide, zirconium oxide, aluminum oxide, and the like.

### First Phosphor

A first phosphor may have an emission peak in the wavelength range of 520 nm to 545 nm. The peak emission wavelength of the light from the first phosphor may preferably be 530 nm or higher, and preferably 540 nm or lower. The half-value width of the peak emission wavelength of the first phosphor may be, for example, 90 nm to 130 nm, preferably 100 nm or higher, and preferably 120 nm or lower.

The first phosphor may have a composition that includes: a first element including at least one selected from the group consisting of yttrium (Y), lutetium (Lu), gadolinium (Gd), and terbium (Tb); a second element including at least one selected from the group consisting of aluminum (Al) and gallium (Ga); oxygen (O); and cerium (Ce). The first element includes at least yttrium (Y), and may further include at least one selected from the group consisting of lutetium (Lu), gadolinium (Gd), and terbium (Tb). For the second element, both aluminum (Al) and gallium (Ga) may be included.

The first phosphor may have a composition in which, assuming that the number of moles of oxygen is 12, the number of moles of the first element is 2.8 to 3.2, the number of moles of the second element is 4.8 to 5.2, and the number of moles of cerium is 0.009 to 0.6. The composition of the first phosphor may preferably be such that, assuming that the number of moles of oxygen is 12, the number of moles of the first element is 2.9 to 3.1, the number of moles of the second element 4.9 to 5.1, and the number of moles of cerium 0.01 to 0.1.

The first phosphor may have a composition represented by the formula (1) below, for example.

(Y,Lu,Gd,Tb)ₓ(Al,Ga)_{y}O₁₂:Ce_{z} (1)

In the formula (1), x, y, and z may satisfy: 2.8≤x≤3.2, 4.8≤y≤5.2, and 0.009≤z≤0.6, preferably 2.9≤x≤3.1, 4.9≤y≤5.1, and 0.010≤z≤0.5.

The first phosphor may include a phosphor essentially having the theoretical composition represented by the formula (1a) below. A theoretical composition means a composition that is stoichiometrically consistent.

Y₃(Al,Ga)₅O₁₂:Ce (1a)

The content percentage of the first phosphor in the wavelength conversion member may be, for example, 50 mass percent to 80 mass percent relative to the total mass of the phosphors contained in the wavelength conversion member. The first phosphor content percentage may preferably be 60 mass percent or higher or 65 mass percent or higher, and preferably 75 mass percent or lower or 70 mass percent or lower. The wavelength conversion member may include a first phosphor of a single type, or two or more in combination.

In the case in which the correlated color temperature of the light emitted from the light emitting device is 6000 K or higher, but lower than 7000 K, the content percentage of the first phosphor in the wavelength conversion member may be, for example, 50 mass percent to 80 mass percent relative to the total mass of the phosphors contained in the wavelength conversion member. The first phosphor content percentage may preferably be 55 mass percent or higher, or 65 mass percent or higher, and preferably 75 mass percent or lower or 70 mass percent or lower. In the case in which the correlated color temperature of the light emitted from the light emitting device is 7000 K to 9200 K, the content percentage of the first phosphor in the wavelength conversion member may be, for example, 50 mass percent to 80 mass percent relative to the total mass of the phosphors contained in the wavelength conversion member. The first phosphor content percentage may preferably be 60 mass percent or higher, or 65 mass percent or higher, and preferably 75 mass percent or lower or 70 mass percent or lower.

The wavelength conversion member may include a phosphor having the theoretical composition represented by the formula (1b) below. In the case in which the wavelength conversion member includes a phosphor having the theoretical composition represented by the formula (1b) below, the content percentage of the phosphor having the theoretical composition represented by the formula (1b) in the wavelength conversion member may be, for example, 15 mass percent or lower relative to the total mass of the phosphors contained in the wavelength conversion member. The content percentage of the phosphor having the theoretical composition represented by the formula (1b) may preferably be 10 mass percent or lower, 5 mass percent or lower, or 1 mass percent or lower. The lower limit of the content percentage of the phosphor having the theoretical composition represented by the formula (1b) may be, for example, 0.1 mass percent or higher. Setting the content percentage of the phosphor having the theoretical composition represented by the formula (1b) as the first phosphor to 15 mass percent or lower, or substantially zero, can reduce the yellow component near 555 nm of the light emitted from the light emitting device, thereby relatively increasing the blue component. This, as a result, can allow a person with reduced visual sensitivity to blue light to visually recognize an object irradiated by the light from the light emitting device of the present disclosure as if the object is irradiated by light having chromaticity coordinates in the vicinity of the blackbody radiation locus based on the visible spectrum estimated for the person.

Y₃Al₅O₁₂:Ce (1b)

### Second Phosphor

A second phosphor may emit light having a peak wavelength in the 605 nm to 670 nm range. The peak emission wavelength of the light from the second phosphor may preferably be 610 nm or higher, and preferably 620 nm or lower. The half-value width of the peak emission wavelength of the second phosphor may be, for example, 70 nm to 90 nm, preferably 80 nm or lower.

The second phosphor may have a composition that includes a third element including at least one selected from the group consisting of calcium and strontium, aluminum, silicon, nitrogen atom, and europium. The second phosphor may have a composition in which, assuming that the number of moles of aluminum is 1, the number of moles of the third element is 0.7 to 1.2, the number of moles of silicon is 0.8 to 1.2, the number of moles of nitrogen atom is 2.0 to 3.2, and the number of moles of europium is 0.002 to 0.05. The composition of the second phosphor may preferably be such that, assuming that the number of moles of aluminum is 1, the number of moles of the third element is 0.9 to 1.0, the number of moles of silicon 0.9 is to 1.1, the number of moles of nitrogen atom is 2.3 to 3.0, and the number of moles of europium is 0.005 to 0.01.

The second phosphor may have a composition represented by the formula (2) below, for example.

CaₚSr_{q}SiₛAlₜNᵤ:Euᵣ (2)

In the formula (2), p, q, r, s, t, and u may satisfy: 0<p<1, 0≤q<1, 0.002≤r≤0.05, 0.8≤p+q+r≤1.1, 0.8≤s≤1.2, 0.8≤t≤1.2, 1.8≤s+t≤2.2, and 2.5≤u≤3.2, preferably 0.02≤p≤0.1, 0≤q≤0.95, 0.005≤r≤0.01, 0.9≤p+q+r≤1.0, 0.9≤s≤1.1, 0.9≤t≤1.1, 1.9≤s+t≤2.1, and 2.7≤u≤3.2.

The second phosphor may include a phosphor essentially having the theoretical composition represented by the formula (2a) below.

(Sr,Ca)AlSiN₃:Eu (2a)

The content percentage of the second phosphor in the wavelength conversion member may be, for example, 1 mass percent to 20 mass percent relative to the total mass of the phosphors contained in the wavelength conversion member. The second phosphor content percentage may preferably be 3 mass percent or higher, 4 mass percent or higher, 4.5 mass percent or higher, or 5 mass percent or higher, and preferably 10 mass percent or lower, 7 mass percent or lower, or 6 mass percent or lower. The wavelength conversion member may include a second phosphor of a single type, or two or more in combination.

In the case in which the correlated color temperature of the light emitted from the light emitting device is 6000 K or higher, but lower than 7000 K, the content percentage of the second phosphor in the wavelength conversion member may be, for example, 1 mass percent to 20 mass percent relative to the total mass of the phosphors contained in the wavelength conversion member. The second phosphor content percentage may preferably be 3 mass percent or higher, 4 mass percent or higher, 4.5 mass percent or higher, or 5 mass percent or higher, and preferably 10 mass percent or lower, 7 mass percent or lower, 6 mass percent or lower, or 5 mass percent or lower. In the case in which the correlated color temperature of the light emitted from the light emitting device is 7000 K to 9200 K, the content percentage of the second phosphor in the wavelength conversion member may be, for example, 1 mass percent to 20 mass percent relative to the total mass of the phosphors contained in the wavelength conversion member. The second phosphor content percentage may preferably be 3 mass percent or higher, 4 mass percent or higher, or 5 mass percent or higher, and preferably 10 mass percent or lower or 6 mass percent or lower.

### Third Phosphor

A third phosphor may emit light having a peak emission wavelength in the 610 nm to 650 nm range. The peak emission wavelength of the light from the third phosphor may preferably be 620 nm or higher, and preferably 640 nm or lower. The half-value width of the emission peak of the third phosphor is, for example, 1 nm to 15 nm, preferably 3 nm or higher, and preferably 12 nm or lower or 10 nm or lower.

The third phosphor may have a composition that includes: a fourth element including at least one selected from the group consisting of alkali metals; a fifth element including at least one selected from the group consisting of titanium, zirconium, hafnium, boron, aluminum, gallium, indium, thallium, carbon, silicon, germanium, and tin; a fluorine atom; and manganese.

The fourth element includes potassium, and may further include at least one selected from the group consisting of lithium, sodium, rubidium, and cesium. The fourth element in the composition of the third phosphor may be essentially composed of potassium. Here, “essentially composed of potassium” means that the ratio of the number of moles of potassium to the total number of moles of the fourth element contained in the composition is, for example, 0.90 or higher, preferably 0.95 or higher, or 0.97 or higher. The upper limit of the ratio of the number of moles can be, for example, 1 or 0.995 or lower. In the third phosphor, the fourth element may be substituted with ammonium ions (NH⁴⁺) in part. In the case in which the fourth element is substituted with ammonium ions (NH⁴⁺) in part, the ratio of the number of moles of ammonium ions to the total number of moles of the fourth element in the composition may be, for example, 0.10 or lower, preferably 0.05 or lower or 0.03 or lower. The lower limit of the ratio of the number of moles of ammonium ions may exceed 0, for example, preferably 0.005 or higher.

The fifth element may include at least one selected from the group consisting of carbon, silicon, germanium, and tin, preferably at least one of silicon and germanium, more preferably at least silicon. The fifth element may include at least one selected from the group consisting of boron, aluminum, gallium, indium, and thallium, and at least one selected from the group consisting of carbon, silicon, germanium, and tin, preferably at least aluminum and at least one of silicon and germanium, more preferably at least aluminum and silicon.

The third phosphor may have a composition in which, assuming that the number of moles of the fourth element is 2, the number of moles of the fifth element is 0.7 to 1.1, the number of moles of fluorine atom is 5.8 to 6.2, and the number of moles of manganese is greater than 0 but smaller than 0.2. The composition of the third phosphor may preferably be such that, assuming that the number of moles of the alkali metal is 2, the number of moles of the fifth element is 0.8 to 1.05, the number of moles of fluorine atom is 5.9 to 6.1, and the number of moles of manganese is 0.01 to 0.15.

The third phosphor may have a composition represented by the formula (3) below, for example.

(K,Li,Na,Rb,Cs)₂(Al,Ga,Si,Ge)ᵢFⱼ:Mnₖ (3)

In the formula (3), i, j, and k may satisfy: 0.7≤i≤1.1, 5.8≤j≤6.2, and 0<k<0.2, preferably 0.8≤i≤1.05, 5.9≤j≤6.1, and 0.01≤k≤0.15.

The third phosphor may include a phosphor having a composition represented by the formula (3a) or (3b) below.

A¹_{c}[M¹_{1-b}F_{d}]:Mn_{b} (3a)

In the formula (3a), A¹ may include at least one selected from the group consisting of Li, Na, K, Rb, and Cs. M¹ includes at least one of Si and Ge, and may further include at least one element selected from the group consisting of the group 4 elements and group 14 elements. Mn may be a tetravalent Mn ion. In the formula, b satisfies 0<b<0.2, c is the absolute value of the charge of the [M²_{1-b}Mn_{b}F_{d}] ion, and d satisfies 5<d<7.

In the formula (3a), A¹ includes at least K, and may further include at least one selected from the group consisting of Li, Na, Rb, and Cs. Moreover, A¹ may be substituted with ammonium ions (NH₄⁺) in part. In the case in which A¹ is substituted with ammonium ions (NH₄⁺) in part, the ratio of the number of moles of the ammonium ions to the total number of moles of A¹ in the composition may be, for example, 0.10 or lower, preferably 0.05 or lower or 0.03 or lower. The lower limit of the ratio of the number of moles of the ammonium ions may exceed 0, for example, preferably 0.005 or higher.

In the formula (3a), b is preferably 0.005 to 0.15, 0.01 to 0.12, or 0.015 to 0.1. In the formula, c may be 1.8 to 2.2, for example, preferably 1.9 to 2.1 or 1.95 to 2.05. In the formula, d may preferably be 5.5 to 6.5, 5.9 to 6.1, 5.92 to 6.05, or 5.95 to 6.025.

A²_{f}[M²₁₋ₑF_{g}]:Mnₑ (3b)

In the formula (3b), A² includes at least K, and may further include at least one selected from the group consisting of Li, Na, Rb, and Cs. M² includes at least Si and Al, and may further include at least one element selected from the group consisting of the group 4 elements, group 13 elements, and group 14 elements. Mn may be tetravalent Mn ion. In the formula, e satisfies 0<e<0.2, f is the absolute value of the charge of the [M²₁₋ₑMnₑF_{g}] ion, and g satisfies 5<g<7.

In the formula (3b), A² may be substituted with ammonium ions (NH₄⁺) in part. In the case in which A² is substituted with ammonium ions (NH₄⁺) in part, the ratio of the number of moles of the ammonium ions to the total number of moles of A² in the composition may be, for example, 0.10 or lower, preferably 0.05 or lower or 0.03 or lower. The lower limit of the ratio of the number of moles of the ammonium ions may exceed 0, for example, preferably 0.005 or higher.

In the formula (3b), e is preferably 0.005 to 0.15, 0.01 to 0.12, or 0.015 to 0.1. In the formula, f may be 1.8 to 2.2, for example, preferably 1.9 to 2.1 or 1.95 to 2.05. In the formula, g may preferably be 5.5 to 6.5, 5.9 to 6.1, 5.92 to 6.05, or 5.95 to 6.025.

The content percentage of the third phosphor in the wavelength conversion member may be, for example, 10 mass percent to 40 mass percent relative to the total mass of the phosphors contained in the wavelength conversion member. The third phosphor content percentage may preferably be 20 mass percent or higher or 25 mass percent or higher, and preferably 35 mass percent or lower, or 30 mass percent or lower. The wavelength conversion member may include a third phosphor of a single type, or two or more in combination.

In the case in which the correlated color temperature of the light emitted from the light emitting device is 6000 K or higher, but lower than 7000 K, the content percentage of the third phosphor in the wavelength conversion member may be, for example, 10 mass percent to 40 mass percent relative to the total mass of the phosphors contained in the wavelength conversion member. The third phosphor content percentage may preferably be 20 mass percent or higher or 25 mass percent or higher, and preferably 35 mass percent or lower, 30 mass percent or lower, or 28 mass percent or lower. In the case in which the correlated color temperature of the light emitted from the light emitting device is 7000 K to 9200 K, the third phosphor content percentage in the wavelength conversion member may be, for example, 10 mass percent to 40 mass percent relative to the total mass of the phosphors contained in the wavelength conversion member. The third phosphor content percentage may preferably be 20 mass percent or higher, 25 mass percent or higher, or 28 mass percent or higher, and preferably 35 mass percent or lower or 30 mass percent or lower.

The total content percentage of the second and third phosphors in the wavelength conversion member may be, for example, 20 mass percent to 50 mass percent relative to the total mass of the phosphors contained in the wavelength conversion member. The total content percentage of the second and third phosphors may preferably be 25 mass percent or higher or 30 mass percent or higher, and preferably 40 mass percent or lower or 35 mass percent or lower.

In the case in which the correlated color temperature of the light emitted from the light emitting device is 6000 K or higher, but lower than 7000 K, the total content percentage of the second and third phosphors in the wavelength conversion member may be, for example, 20 mass percent to 50 mass percent relative to the total mass of the phosphors contained in the wavelength conversion member. The total content percentage of the second and third phosphors may preferably be 25 mass percent or higher or 30 mass percent or higher, and preferably 40 mass percent or lower, 35 mass percent or lower, or 32 mass percent or lower. Moreover, in the case in which the correlated color temperature of the light emitted from the light emitting device is 7000 K to 9200 K, the total content percentage of the second and third phosphors in the wavelength conversion member may be 20 mass percent to 50 mass percent relative to the total mass of the phosphors contained in the wavelength conversion member. The total content percentage of the second and third phosphors may preferably be 25 mass percent or higher, 30 mass percent or higher, or 32 mass percent or higher, and preferably 40 mass percent or lower, 38 mass percent or lower, or 35 mass percent or lower.

The ratio of the second phosphor content to the total content of the second and third phosphors in the wavelength conversion member may be, for example, 0.01 to 0.5, preferably 0.05 or higher or 0.1 or higher, and preferably 0.3 or lower or 0.2 or lower.

The ratio of the first phosphor content to the total content of the second and third phosphors in the wavelength conversion member may be, for example, 1.5 to 3, preferably 1.6 or higher, 1.8 or higher, or 1.9 or higher, and preferably 2.6 or lower, 2.4 or lower, or 2.3 or lower.

In the case in which the correlated color temperature of the light emitted from the light emitting device is 6000 K or higher, but lower than 7000 K, the ratio of the first phosphor content to the total content of the second and third phosphors in the wavelength conversion member may be, for example, 1.5 to 3. The ratio of the first phosphor content may preferably be 1.6 or higher, 1.8 or higher, 2.0 or higher, or 2.2 or higher, and preferably 2.5 or lower, 2.4 or lower, 2.3 or lower, or 2 or lower. In the case in which the correlated color temperature of the light emitted from the light emitting device is 7000 K to 9200 K, the ratio of the first phosphor content to the total content of the second and third phosphors in the wavelength conversion member may be, for example, 1.5 to 3. The ratio of the first phosphor content may preferably be 1.7 or higher, 1.8 or higher, 1.9 or higher, or 2 or higher, and preferably 2.6 or lower, 2.3 or lower, 2.2 or lower, or 2 or lower.

### Fourth Phosphor

A fourth phosphor may have a peak emission wavelength in a range of 505 nm to 530 nm. The peak emission wavelength of the fourth phosphor may preferably be 510 nm or higher. The half-value width of the emission peak of the fourth phosphor may be, for example, 30 nm to 70 nm, preferably 40 nm or higher and preferably 60 nm or lower.

The fourth phosphor may have a composition including: an alkali-earth metal including at least one selected from the group consisting of calcium, strontium, and barium; magnesium; silicon; oxygen; a halogen atom including at least one selected from the group consisting of fluorine, chlorine, and bromine; and europium.

The fourth phosphor may include a phosphor essentially having the theoretical composition represented by the formula (4a) below.

Ca₈MgSi₄O₁₆Cl₂:Eu (4a)

The content percentage of the fourth phosphor in the wavelength conversion member may be, for example, 17 mass percent to 35 mass percent relative to the total mass of the phosphors contained in the wavelength conversion member. The fourth phosphor content percentage may preferably be 22 mass percent or higher, or 30 mass percent or higher. The wavelength conversion member may include a fourth phosphor of a single type, or two or more in combination.

The total content percentage of the second and fourth phosphors in the wavelength conversion member may be, for example, 20 mass percent to 50 mass percent relative to the total mass of the phosphors contained in the wavelength conversion member. The total content percentage of the second and fourth phosphors may preferably be 25 mass percent or higher, 30 mass percent or higher, or 34 mass percent or higher, and preferably 40 mass percent or lower or 38 mass percent or lower.

The ratio of the fourth phosphor content to the total content of the second and fourth phosphors in the wavelength conversion member may be, for example, 0.1 to 0.4, preferably 0.2 or higher or 0.22 or higher, and preferably 0.35 or lower or 0.3 or lower.

The ratio of the first phosphor content to the total content of the second and fourth phosphors in the wavelength conversion member may be, for example, 1.2 to 3, preferably 1.4 or higher or 1.6 or higher, and preferably 2.4 or lower or 2.0 or lower.

In the case in which the wavelength conversion member includes the first to third phosphors, the total content of the phosphors in the wavelength conversion member per 100 parts by mass of the resin may be, for example 10 parts by mass to 50 parts by mass, preferably 15 parts by mass or higher, 18 parts by mass or higher, or 20 parts by mass or higher, and preferably 40 parts by mass or lower, 30 parts by mass or lower, or 28 parts by mass or lower.

In the case in which the wavelength conversion member includes the first to third phosphors and the correlated color temperature of the light emitted from the light emitting device is 6000 K or higher, but lower than 7000 K, the total phosphor content in the wavelength conversion member per 100 parts by mass of the resin may be, for example, 10 parts by mass to 50 parts by mass, preferably 15 parts by mass or higher, 18 parts by mass or higher, or 20 parts by mass or higher, and preferably 40 parts by mass or lower, 30 parts by mass or lower, 25 parts by mass or lower, or 22 parts by mass or lower. In the case in which the correlated color temperature of the light emitted from the light emitting device is 7000 K to 9200 K, the total phosphor content in the wavelength conversion member per 100 parts by mass of the resin may be, for example, 10 parts by mass to 50 parts by mass, preferably 15 parts by mass or higher, 18 parts by mass or higher, 20 parts by mass or higher, or 22 parts by mass or higher, and preferably 40 parts by mass or lower, 30 parts by mass or lower, or 28 parts by mass or lower.

In the case in which the wavelength conversion member includes the first, second, and fourth phosphors, the total phosphor content in the wavelength conversion member per 100 parts by mass of the resin may be, for example, 4 parts by mass to 20 parts by mass, preferably 7 parts by mass or higher, 8 parts by mass or higher, or 10 parts by mass or higher, and preferably 18 parts by mass or lower, 16 parts by mass or lower, or 14 parts by mass or lower.

### Light Source Device

A light source device may include a first light emitting device emitting light having a correlated color temperature of 7000 K to 9200 K and a second light emitting device emitting light having a correlated color temperature of 2600 K to 2900 K. The light source device may be configured such that the color of the emitted light can be adjusted in the 2600 K to 9200 K correlated color temperature range. Here, the first light emitting device may be any of the light emitting devices described earlier.

The first light emitting device included in the light source device may include a light emitting element emitting light having a peak emission wavelength in the range of 440 nm to 470 nm and a wavelength conversion member including multiple phosphors which emit light when excited by the light from the light emitting element. In the emission spectrum of the first light emitting device, the ratios of the luminous intensity at wavelengths 480 nm, 530 nm, and 550 nm to the luminous intensity of the emission peak attributed to the light emitting element at the peak emission wavelength may be 0.15 to 0.20, 0.20 to 0.35, and 0.25 to 0.38, respectively. The details of the constituents of the first light emitting device are similar to those of the light emitting device described earlier.

The correlated color temperature of the light emitted from the first light emitting device may preferably be 7200 K or higher or 7500 K or higher, and preferably 9000 K or lower or 8500 K or lower.

The second light emitting device included in the light source device emits light having a correlated color temperature of 2600 K to 2900 K. The correlated color temperature of the light emitted from the second light emitting device may preferably be 2620 K or higher, or 2650 K or higher, and preferably 2900 K or lower, or 2800 K or lower.

The second light emitting device may be configured in the same or a similar manner to the first light emitting device except for being configured to emit light having a correlated color temperature in the range described above. The second light emitting device may be configured differently from the first light emitting device. The second light emitting device may include, for example, a light emitting element emitting light having a peak emission wavelength in the range of 440 nm to 470 nm and a wavelength conversion member including multiple phosphors that emit light when excited by the light from the light emitting element. The light emitting element included in the second light emitting device may be the same as or similar to the light emitting element included in the first light emitting device.

The wavelength conversion member included in the second light emitting device can include, for example, a phosphor and a resin. The wavelength conversion member may include phosphors of at least one type of fifth phosphors that absorbs the light from the light emitting element and emits green light, at least one type of sixth phosphors that absorbs the light from the light emitting element and emits red light, and at least one type of seventh phosphors that absorbs the light from the light emitting element and emits deep red light. The fifth to seventh phosphors have different compositions from one another. Suitably selecting the composition ratio of the fifth to seventh phosphors can have desired ranges of the luminescence efficiency of the second light emitting device and of the chromaticity coordinates of the emitted light. For the resin included in the wavelength conversion member, the same or a similar resin to that included in the light emitting devices described above can be used.

### Fifth Phosphor

A fifth phosphor may emit light having a peak emission wavelength in the range of 510 nm to 545 nm. The peak emission wavelength of the light from the fifth phosphor may preferably be 520 nm or higher, and preferably 535 nm or higher. The half-value width of the emission peak of the fifth phosphor may be, for example, 80 nm to 120 nm, preferably 90 nm or higher and preferably 110 nm or lower.

The fifth phosphor may have a composition that includes: a sixth element including at least one selected from the group consisting of yttrium (Y), lutetium (Lu), gadolinium (Gd), and terbium (Tb); a seventh element including at least one selected from the group consisting of aluminum (Al) and gallium (Ga); oxygen; and cerium. The sixth element includes at least yttrium (Y), and may further include at least one selected from the group consisting of lutetium (Lu), gadolinium (Gd), and terbium (Tb). The sixth element includes at least lutetium (Lu), and may further include at least one selected from the group consisting of yttrium (Y), gadolinium (Gd), and terbium (Tb). For the seventh element, both aluminum (Al) and gallium (Ga) may be included.

The fifth phosphor may have a composition in which, assuming that the number of moles of oxygen is 12, the number of moles of the sixth element is 2.8 to 3.2, the number of moles of the seventh element is 4.8 to 5.2, and the number of moles of cerium is 0.009 to 0.6. The composition of the fifth phosphor may preferably be such that, assuming that the number of moles of oxygen is 12, the number of moles of the sixth element may be 2.9 to 3.1, the number of moles of the seventh element may be 4.9 to 5.1, and the number of moles number of cerium may be 0.01 to 0.2.

The fifth phosphor may have a composition represented by the formula (5) below, for example.

(Y,Lu,Gd,Tb)ₓ(Al,Ga)_{y}O₁₂:Ce_{z} (5)

In the formula (5), x, y, and z may satisfy: 2.8≤x≤3.2, 4.8≤y≤5.2, and 0.009≤z≤0.6, preferably 2.9≤x≤3.1, 4.9≤y≤5.1, and 0.01≤z≤0.2.

The fifth phosphor may include a phosphor essentially having the theoretical composition represented by the formula (5a) or (5b) below.

Y₃(Al,Ga)₅O₁₂:Ce (5a)

Lu₃(Al,Ga)₅O₁₂:Ce (5b)

The content percentage of the fifth phosphor in the wavelength conversion member may be, for example, 1 mass percent to 95 mass percent relative to the total mass of the phosphors contained in the wavelength conversion member. The fifth phosphor content percentage may preferably be 20 mass percent or higher, 30 mass percent or higher, 40 mass percent or higher, or 50 mass percent or higher, and preferably 70 mass percent or lower, 60 mass percent or lower, 55 mass percent or lower, or 50 mass percent or lower. The wavelength conversion member may include a fifth phosphor of a single type, or two or more in combination.

The fifth phosphor in the second light emitting device may include a phosphor having the composition represented by the formula (5a) and a phosphor having the composition represented by the formula (5b). In the case in which the fifth phosphor include a phosphor having the composition represented by the formula (5a) and a phosphor having the composition represented by the formula (5b), the content percentage of the phosphor having the composition of formula (5a) relative to the total content of the fifth phosphor may be, for example, 5 mass percent to 95 mass percent, preferably 10 mass percent or higher, 15 mass percent or higher, 20 mass percent or higher, 30 mass percent or higher, or 50 mass percent or higher, and preferably 70 mass percent or lower, 60 mass percent or lower, 40 mass percent or lower, 30 mass percent or lower, or 25 mass percent or lower.

### Sixth Phosphor

A sixth phosphor may emit light having a peak emission wavelength in the range of 590 nm to 620 nm. Except for the difference in terms of the peak emission wavelength range, the emission properties and the composition of the sixth phosphor may be the same or similar to those of the second phosphor described earlier.

The content percentage of the sixth phosphor in the wavelength conversion member may be, for example, 1 mass percent to 20 mass percent relative to the total mass of the phosphors contained in the wavelength conversion member. The sixth phosphor content percentage may preferably be 1.5 mass percent or higher, 2 mass percent or higher, 2.2 mass percent or higher, or 5 mass percent or higher, and preferably 15 mass percent or lower, 10 mass percent or lower, or 5 mass percent or lower. The wavelength conversion member may include a sixth phosphor of a single type, or two or more in combination.

### Seventh Phosphor

A seventh phosphor may emit light having a peak emission wavelength in the range of 620 nm to 650 nm. Except for the difference in terms of the peak emission wavelength range, the emission properties and the composition of the seventh phosphor may be the same or similar to those of the third phosphor described earlier.

The content percentage of the seventh phosphor in the wavelength conversion member may be, for example, 1 mass percent to 60 mass percent relative to the total mass of the phosphors contained in the wavelength conversion member. The seventh phosphor content percentage may preferably be 2 mass percent or higher, 5 mass percent or higher, 20 mass percent or higher, 30 mass percent or higher, or 40 mass percent or higher, and preferably 50 mass percent or lower, 45 mass percent or lower, 15 mass percent or lower, or 10 mass percent or lower. The wavelength conversion member may include a seventh phosphor of a single type, or two or more in combination.

The ratio of the sixth phosphor content to the total content of the sixth and seventh phosphors in the wavelength conversion member may exceed 0 but lower than 1, for example, preferably 0.02 or higher, 0.03 or higher, 0.04 or higher, or 0.05 or higher, and preferably 0.15 or lower, 0.1 or lower, 0.08 or lower, or 0.06 or lower.

The ratio of the fifth phosphor content to the total content of the sixth and seventh phosphors in the wavelength conversion member may be, for example, 0.1 to 1.4, preferably 0.15 or higher, 0.2 or higher, 0.6 or higher, 0.8 or higher, 1 or higher, or 1.1 or higher, and preferably 1.3 or lower, 1.2 or lower, 1 or lower, 0.35 or lower, or 0.3 or lower.

The total phosphor content in the wavelength conversion member per 100 parts by mass of the resin may be, for example, 30 parts by mass to 150 parts by mass, preferably 70 parts by mass or higher, or 80 parts by mass or higher, and preferably 120 parts by mass or lower, or 100 parts by mass or lower.

The light source device is configured such that the color of the emitted light can be adjusted in the 2600 K to 9200 K correlated color temperature range. The correlated color temperature of the light emitted from the light source device may preferably be 2650 K or higher and preferably 9000 K or lower, or 8500 K or lower. By including the first light emitting device and the second light emitting device, the correlated color temperature of the light emitted from the light source device can be adjusted in a predetermined range. Specifically, for example, adjusting the current applied to each of the first light emitting device and the second light emitting device can make the correlated color temperature of the light emitted from the light source device to fall within a predetermined range.

The light source device is constituted with, for example, a first light emitting device, a second light emitting device, a control part for controlling the optical outputs of the first and second light emitting devices to achieve a predetermined correlated color temperature, and a setting part for setting a predetermined color with the control part. The light source device can emit mixed color light having a predetermined correlated color temperature and chromaticity coordinates by controlling the optical outputs of the first and second light emitting devices. Employing a first light emitting device and a second light emitting device each emitting light having a predetermined color deviation allows the light source device to emit mixed color light from a low correlated color temperature to a high correlated color temperature having a color deviation duv from the blackbody radiation locus in the range of −0.015 to −0.001.

The light emitted from the light source device may be in the color deviation duv range of −0.015 to −0.001 from the blackbody radiation locus in the CIE 1931 chromaticity diagram. The color deviation duv of the light from the light source device may preferably be −0.0135 or higher, −0.012 or higher, or −0.010 or higher, and preferably-0.003 or lower, or −0.005 or lower.

### EXAMPLES

The present invention will be described specifically by way of examples below, but the present invention is not limited to these examples.

### Phosphor

Before producing a light emitting device, the first phosphor, the second phosphor, the third phosphor, and the fourth phosphor described below were prepared.

As a first phosphor, a green light emitting phosphor essentially having the theoretical composition represented by Y₃(Al,Ga)₅O₁₂:Ce and emitting light having a peak emission wavelength near 535 nm (hereinafter occasionally referred to as “GYAG”) was prepared.

As a second phosphor, a red light emitting phosphor essentially having the theoretical composition represented by (Sr,Ca)AlSiN₃:Eu and emitting light having a peak emission wavelength near 610 nm (hereinafter occasionally referred to as “SCASN”) was prepared.

As a third phosphor, a deep red light emitting phosphor essentially having the theoretical composition represented by K₂SiF₆:Mn and emitting light having a peak emission wavelength near 630 nm (hereinafter occasionally referred to as “KSF”) was prepared. The half-value width of the emission spectrum of the KSF was 8 nm.

As a fourth phosphor, a green light emitting phosphor essentially having the theoretical composition represented by Ca₈MgSiO₁₆Cl₂:Eu and emitting light having a peak emission wavelength near 515 nm (hereinafter occasionally referred to as “halosilicate”) was prepared.

As other phosphors, a yellow light emitting phosphor essentially having the theoretical composition represented by Y₃Al₅O₁₂:Ce and emitting light having a peak emission wavelength near 555 nm (hereinafter occasionally referred to as “YAG”) and a green light emitting phosphor essentially having the theoretical composition represented by Lu₃(Al,Ga)₅O₁₂:Ce and emitting light having a peak emission wavelength near 525 nm (hereinafter occasionally referred to as “LAG”) were prepared.

### Light Emitting Element

As a light emitting element, an LED emitting blue-violet light having a peak emission wavelength of 455 nm was prepared.

### Example 1

### Producing of Light Emitting Device

A light emitting device of Example 1 was produced as described below by combining an LED emitting blue-violet light having a peak emission wavelength of 455 nm, a first phosphor (GYAG), a second phosphor (SCASN), and a third phosphor (KSF).

The phosphors were mixed such that the content percentage of the first phosphor (GYAG) was 65.5 mass percent and the total content percentage of the second phosphor (SCASN) and the third phosphor (KSF) was 34.5 mass percent relative to the total phosphor amount, the mass based mixture ratio of the second phosphor (SCASN) to the third phosphor (KSF) (SCASN: KSF) was 15:85, and the correlated color temperature to be achieved was approximately 6500 K. The phosphor mixture was added to a silicone resin to be blended and dispersed. Subsequently, the resin was degassed to obtain a phosphor-containing resin composition. Here, the total amount of phosphors per 100 parts by mass of the silicone resin was 25 parts by mass. Then the phosphor-containing resin composition was supplied on the light emitting element and in the cavity, and hardened by heating. A light emitting device in Example 1 was produced by following the steps described above.

### Example 2

A light emitting device in Example 2 was produced in the same or a similar manner to in Example 1 except for mixing the phosphors such that the content percentage of the first phosphor (GYAG) was 69.2 mass percent and the total content percentage of the second phosphor (SCASN) and the third phosphor (KSF) was 30.8 mass percent relative to the total phosphor amount, the mass based mixture ratio of the second phosphor (SCASN) to the third phosphor (KSF) (SCASN: KSF) was 15:85, the correlated color temperature to be achieved was approximately 7870 K, and the total amount of phosphors per 100 parts by mass of the silicone resin was 20.5 parts by mass.

### Example 3

A light emitting device in Example 3 was produced in the same or a similar manner to in Example 1 except for mixing the phosphors such that the content percentage of the first phosphor (GYAG) was 64.0 mass percent and the total content percentage of the second phosphor (SCASN) and the fourth phosphor (halosilicate) was 36.0 mass percent relative to the total phosphor amount, the mass based mixture ratio of the second phosphor (SCASN) to the fourth phosphor (halosilicate) (SCASN: halosilicate) was 73:27, the correlated color temperature to be achieved was approximately 8500 K, and the total amount of phosphors per 100 parts by mass of the silicone resin was 11.8 parts by mass.

### Comparative Example 1

A light emitting device in Comparative Example 1 was produced in the same or a similar manner to in Example 1 except for mixing the phosphors such that the total content percentage of the first phosphor (GYAG) and YAG relative to the total phosphor amount was 56.1 mass percent, the mass based mixture ratio of the first phosphor (GYAG) to YAG (GYAG:YAG) was 80:20, the total content percentage of the second phosphor (SCASN) and the third phosphor (KSF) was 43.9 mass percent, the mass based mixture ratio of the second phosphor (SCASN) to the third phosphor (KSF) (SCASN:KSF) was 3:97, the correlated color temperature to be achieved was approximately 5000 K, and the total amount of phosphors per 100 parts by mass of the silicone resin was 44.7 parts by mass.

### Comparative Example 2

A light emitting device in Comparative Example 2 was produced in the same or a similar manner to in Example 1 except for mixing the phosphors such that the total content percentage of the first phosphor (GYAG) and YAG relative to the total phosphor amount was 63 mass percent, the mass based mixture ratio of the first phosphor (GYAG) to YAG (GYAG:YAG) was 90:10, the total content percentage of the second phosphor (SCASN) and the third phosphor (KSF) was 37 mass percent, the mass based mixture ratio of the second phosphor (SCASN) to the third phosphor (KSF) (SCASN:KSF) was 3:97, the correlated color temperature to be achieved was approximately 6500 K, and the total amount of phosphors per 100 parts by mass of the silicone resin was 30.5 parts by mass.

### Reference Example 1

A light emitting device in Reference Example 1 was produced in the same or a similar manner to in Example 1 except for mixing the phosphors such that the total content percentage of LAG and GYAG relative to the total phosphor amount was 54.5 mass percent, the mixture ratio of LAG to GYAG (LAG:GYAG) was 80:20, the total content percentage of SCASN and KSF was 45.5 mass percent, the mass based mixture ratio of SCASN to KSF (SCASN:KSF) was 5:95, the correlated color temperature to be achieved was approximately 2700 K, and the total amount of phosphors per 100 parts by mass of the silicone resin was 90 parts by mass.

### Evaluation

### Chromaticity Coordinates (x, y), Color Deviation, Average Color Rendering Ra, Special Color Rendering R9, and Correlated Color Temperature

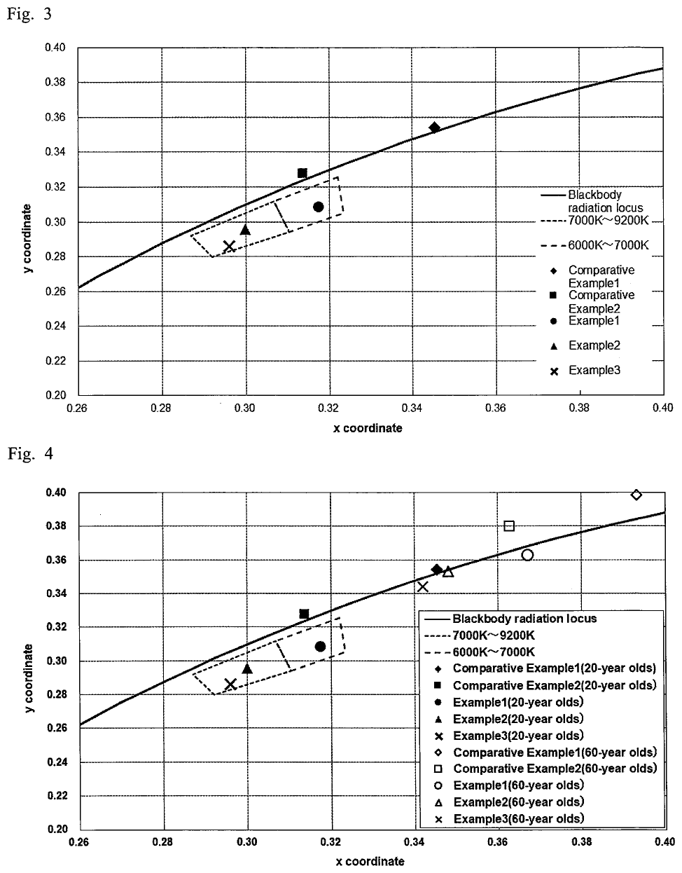

The chromaticity coordinates (x, y) and color deviation of the emission color of the light emitting device in each of the Examples and Comparative Examples were measured by using an optical measurement system that combines a multichannel spectrometer and an integrating sphere. The average color rendering index Ra and special color rendering index R9 were obtained in accordance with JIS Z 8726. Furthermore, the correlated color temperature (Tcp; K) was measured in accordance with JIS Z 8725. Table 1 shows the results. FIG. 3 shows the chromaticity coordinates of the emission color of each light emitting device in the CIE 1931 chromaticity diagram.

### Relative Luminous Flux

With respect to the light emitting device in each of the Examples and Comparative Examples, the luminous flux was measured by using a total flux measurement system that employs an integrating sphere. Assuming that the luminous flux of the light emitting device in Comparative Example 1 which emits light of a correlated color temperature of approximately 5000 K is 100%, the relative luminous flux of the other light emitting devices were calculated.

### Emission Spectrum

By using a total flux measurement system same as or similar to that used to measure the relative luminous flux, the emission spectrum for each light emitting device was measured showing the relative intensity (relative luminous intensity) corresponding to the wavelengths. FIG. 2 shows the emission spectrum of each light emitting device assuming that the maximum value of the luminous intensity in each emission spectrum is 1. In each emission spectrum, the ratios of the luminous intensity at wavelength 480 nm, 500 nm, 530 nm, 550 nm, and 580 nm to the luminous intensity at the peak (455 nm) attributed to the light emitting element were obtained. Table 1 shows the results.

TABLE 1

| | | | | Color | | | | | | | | |
|---|---|---|---|---|---|---|---|---|---|---|---|---|
| | Chromaticity | | | Rendering | | Correlated | Relative | | | | | |
| | Coordinates | | Color | Index | | Color | Flux | Luminous Intensity Ratio | | | | |
| | x | y | Deviation | Ra | R9 | Temp. (K) | (%) | 480 nm | 500 nm | 530 nm | 550 nm | 580 nm |
| Example1 | 0.318 | 0.309 | −0.010 | 93.9 | 90.9 | 6379 | 92.4 | 0.18 | 0.24 | 0.32 | 0.33 | 0.33 |
| Example2 | 0.300 | 0.295 | −0.008 | 93.2 | 87.5 | 7855 | 93.7 | 0.18 | 0.23 | 0.29 | 0.30 | 0.28 |
| Example3 | 0.296 | 0.286 | −0.012 | 91.8 | 79.5 | 8465 | 83.7 | 0.16 | 0.22 | 0.28 | 0.25 | 0.24 |
| Com- | 0.345 | 0.354 | 0.001 | 93.9 | 84.7 | 5001 | 100.0 | 0.21 | 0.36 | 0.50 | 0.51 | 0.46 |
| parative | | | | | | | | | | | | |
| Example1 | | | | | | | | | | | | |
| Com- | 0.314 | 0.327 | 0.002 | 94.2 | 92.8 | 6456 | 97.3 | 0.19 | 0.30 | 0.40 | 0.39 | 0.33 |
| parative | | | | | | | | | | | | |
| Example2 | | | | | | | | | | | | |

### Changes in Chromaticity Coordinates Attributed to Visible Spectrum Change

The light emitting devices obtained above were evaluated in terms of the color coordinates, the color rendering indices, and the correlated color temperature of the emission color perceived by a person with reduced sensitivity to blue light by applying the visible spectrum changes estimated for 60-year old human. Table 2 and FIG. 4 show the results. For the standard visible spectrum, the visible spectrum estimated for 20-year old human was employed.

Specifically, the evaluation was conducted as described below based on the transmittance of light every 5 nm from 300 nm to 700 nm wavelengths estimated for each age described in the CIE Technical Report, CIE 203:2012 incl. Erratum 1. For each wavelength, the transmittance estimated for 60-year olds was divided by the transmittance estimated for 20-year olds, followed by multiplying the value thus obtained by the luminous intensity of the light emitting device at the wavelength to convert the emission spectrum into one that accounts for the visible spectrum changes estimated for 60-year olds. From the converted emission spectrum, the chromaticity coordinates and the correlated color temperature to which the visible spectrum estimated for 60-year olds was applied were calculated based on the conversion method defined by the CIE 1931.

TABLE 2

| | | | | Color | | |
|---|---|---|---|---|---|---|
| | Chromaticity | | | Rendering | | Correlated |
| | Coordinates | | Color | Index | | Color Temp. |
| | x | y | Deviation | Ra | R9 | (K) |
| Example1 | 0.367 | 0.363 | −0.002 | 93.2 | 77.1 | 4299 |
| Example2 | 0.348 | 0.353 | 0.000 | 91.5 | 69.2 | 4896 |
| Example3 | 0.342 | 0.344 | −0.002 | 94.1 | 67.4 | 5115 |
| Comparative | 0.393 | 0.399 | 0.006 | 94.4 | 91.2 | 3836 |
| Example1 | | | | | | |
| Comparative | 0.363 | 0.380 | 0.007 | 93.5 | 98.6 | 4524 |
| Example2 | | | | | | |

As shown in FIG. 4, the color coordinates of the light emitted from the light emitting devices in the Examples using the standard visible spectrum are in the region with negative color deviations relative to the blackbody radiation locus, but are practically on the blackbody radiation locus using the visible spectrum estimated for 60-year olds. This indicates that when a person with the visible spectrum estimated for 60-year olds views an object irradiated by the light from the light emitting devices of the Examples, the discernability of color, letters, or the like is improved. This can provide a light emitting device capable of emitting light having high color rendering by reducing the yellow component while relatively increasing the blue component of the light.

### Example 4

### Color Adjustable Light Source Device

A light emitting device in Example 2 was used as a first light emitting device, and a light emitting device in Reference Example 1 was used as a second light emitting device. A light source device including the first light emitting device, the second light emitting device, a control part capable of controlling the optical outputs of these devices, and a setting part capable of setting a predetermined correlated color temperature in coordination with the control part was produced.

Table 3 shows the chromaticity coordinates (x, y) of the emission colors, color deviations, the average color rendering index Ra and special color rendering index R9 in accordance with JIS Z 8726, and the correlated color temperatures (Tcp; K) in accordance with JIS Z 8725 of the first light emitting device and the second light emitting device used in the light source device in Example 4.

### Evaluation

The light source device was turned on while controlling the ratio of the optical output of the first light emitting device to the optical output of the second light emitting device (the first light emitting device: the second light emitting device) as shown in Table 4 to measure the chromaticity coordinates (x, y) and the color deviations of the emission colors. Furthermore, the average color rendering index Ra and special color rendering index R9 were obtained in accordance with JIS Z 8726. The correlated color temperatures were measured in accordance with JIS Z 8725. Table 4 shows the results.

TABLE 3

| | | | | Color | | |
|---|---|---|---|---|---|---|
| | Chromaticity | | | Rendering | | Correlated |
| | Coordinates | | Color | Index | | Color Temp. |
| | x | y | Deviation | Ra | R9 | (K) |
| First Light | 0.300 | 0.295 | −0.008 | 93.2 | 87.5 | 7855 |
| Emitting Device | | | | | | |
| Second Light | 0.457 | 0.407 | −0.001 | 95.5 | 67.3 | 2710 |
| Emitting Device | | | | | | |

TABLE 4

| Ratio of Output of | | | | Color | | Correlated |
|---|---|---|---|---|---|---|
| First to Second | Chromaticity | | | Rendering | | Color |
| Light Emitting | Coordinates | | Color | Index | | Temp. |
| Device | x | y | Deviation | Ra | R9 | (K) |
| 9:1 | 0.310 | 0.303 | −0.010 | 94.0 | 92.5 | 6943 |
| 8:2 | 0.321 | 0.310 | −0.011 | 94.2 | 93.8 | 6155 |
| 7:3 | 0.333 | 0.319 | −0.012 | 94.3 | 94.0 | 5470 |
| 6:4 | 0.346 | 0.328 | −0.013 | 95.0 | 94.5 | 4875 |
| 5:5 | 0.360 | 0.338 | −0.013 | 95.0 | 93.9 | 4360 |
| 4:6 | 0.376 | 0.349 | −0.012 | 94.9 | 91.3 | 3918 |
| 3:7 | 0.393 | 0.361 | −0.011 | 94.8 | 86.7 | 3541 |
| 2:8 | 0.412 | 0.375 | −0.008 | 94.8 | 80.9 | 3220 |
| 1:9 | 0.433 | 0.390 | −0.005 | 95.1 | 74.3 | 2946 |

The light emitting device according to an embodiment of the present disclosure can improve the discernibility of letters or the like when used by a person with reduced sensitivity to blue light. For example, it can be used as a general lighting fixture installed indoors, such as in an office, home, commercial facility, or plant, automotive light, display, decorative lighting, warning light, security light, display light, or liquid crystal backlight. Furthermore, it can be incorporated in a lighting tool.

The disclosure of Japanese Patent Application No. 2021-176587 (application date: Oct. 28, 2021) and Japanese Patent Application No. 2021-202482 (application date: Dec. 14, 2021) in their entirety is incorporated in the present specification by reference. All publications, patent applications, and technical standards cited in the present specification are incorporated in the present specification by reference to the same extent as in the case in which a publication, patent application, or technical standard is specifically and individually described.

What is claimed is:

1. A light emitting device, comprising:
a light emitting element emitting light having a peak emission wavelength in a range of 440 nm to 470 nm, and
a wavelength conversion member including a plurality of phosphors emitting light when excited by the light from the light emitting element,
wherein a ratio of luminous intensity of light emitted from the light emitting device at wavelength 480 nm in an emission spectrum to luminous intensity of an emission peak attributed to the light emitting element at the peak emission wavelength is 0.05 to 0.20,
wherein a ratio of luminous intensity of the light emitted from the light emitting device at wavelength 530 nm in the emission spectrum to the luminous intensity of the emission peak attributed to the light emitting element at the peak emission wavelength is 0.20 to 0.35, and
wherein a ratio of the luminous intensity of the light emitted from the light emitting device at wavelength 550 nm in the emission spectrum to the luminous intensity of the emission peak attributed to the light emitting element at the peak emission wavelength is 0.23 to 0.38.

2. The light emitting device according to claim 1, wherein the light emitted from the light emitting device has a correlated color temperature that is 6000 K or higher and lower than 7000 K.

3. The light emitting device according to claim 2, wherein the light emitted from the light emitting device has chromaticity coordinates in a quadrilateral having a first point (x=0.322 and y=0.326), a second point (x=0.307 and y=0.312), a third point (x=0.310 and y=0.294), and a fourth point (x=0.324 and y=0.305) as its vertices in a CIE 1931 chromaticity diagram.

4. The light emitting device according to claim 1, wherein the light emitted from the light emitting device has a correlated color temperature that is 7000 K to 9200 K.

5. The light emitting device according to claim 4, wherein the light emitted from the light emitting device has chromaticity coordinates in a quadrilateral having a fifth point (x=0.292 and y=0.280), a sixth point (x=0.287 and y=0.292), a seventh point (x=0.307 and y=0.312), and a eighth point (x=0.310 and y=0.294) as its vertices in a CIE 1931 chromaticity diagram.

6. The light emitting device according to claim 1, a color deviation duv from the blackbody radiation locus of the light emitted from the light emitting device is in a range of −0.015 to −0.001 in a CIE 1931 chromaticity diagram.

7. The light emitting device according to claim 1, wherein a ratio of luminous intensity of the light emitted from the light emitting device at wavelength 500 nm in the emission spectrum to luminous intensity of the emission peak attributed to the light emitting element at the peak emission wavelength is 0.20 to 0.35.

8. The light emitting device according to claim 1, wherein a ratio of luminous intensity of the light emitted from the light emitting device at wavelength 580 nm in the emission spectrum to luminous intensity of the emission peak attributed to the light emitting element at the peak emission wavelength is 0.20 to 0.35.

9. The light emitting device according to claim 1, wherein an emission peak of the light emitted from the light emitting device is in a range of 620 nm to 650 nm in the emission spectrum.

10. The light emitting device according to claim 9, wherein a half-value width of the emission peak in the range of 620 nm to 650 nm in the emission spectrum is 10 nm or lower.

11. The light emitting device according to claim 1, wherein the wavelength conversion member includes a first phosphor having a peak emission wavelength in a range of 520 nm to 545 nm, a second phosphor having a peak emission wavelength in a range of 605 nm to 670 nm, and a third phosphor having a peak emission wavelength in a wavelength range of 610 nm to 650 nm.

12. The light emitting device according to claim 1, wherein the wavelength conversion member includes a first phosphor having a peak emission wavelength in a range of 520 nm to 545 nm, a second phosphor having a peak emission wavelength in a range of 605 nm to 670 nm, and a fourth phosphor including a halogen and having a peak emission wavelength in a range of 505 nm to 530 nm.

13. The light emitting device according to claim 11, wherein
the first phosphor has a composition comprising: a first element including at least one selected from the group consisting of yttrium, lutetium, gadolinium, and terbium; a second element including at least one selected from the group consisting of aluminum and gallium; oxygen; and cerium, and
a number of moles of the first element being 2.8 to 3.2, a number of moles of the second element being 4.8 to 5.2, and a number of moles of cerium being 0.009 to 0.6, assuming that a number of moles of oxygen is 12.

14. The light emitting device according to claim 11, wherein
the second phosphor has a composition comprising: a third element including at least one selected from the group consisting of calcium and strontium; aluminum; silicon; nitrogen; and europium, and
a number of moles of the third element being 0.7 to 1.2, a number of moles of silicon being 0.8 to 1.2, a number of moles of nitrogen being 2.0 to 3.2, and a number of moles of europium being 0.002 to 0.05, assuming that a number of moles of aluminum is 1.

15. The light emitting device according to claim 11, wherein
the third phosphor has a composition comprising: a fourth element including at least one selected from the group consisting of alkali metals; a fifth element including at least one selected from the group consisting of titanium, zirconium, hafnium, boron, aluminum, gallium, indium, thallium, carbon, silicon, germanium, and tin; fluorine; and manganese, and
a number of moles of the fifth element being 0.7 to 1.1, a number of moles of fluorine being 5.8 to 6.2, and a number of moles of manganese being greater than 0 but smaller than 0.2, assuming that a number of moles of the fourth element is 2.

16. The light emitting device according to claim 12, wherein the fourth phosphor comprises: an alkali-earth metal including at least one selected from the group consisting of calcium, strontium, and barium; magnesium; silicon; oxygen; a halogen including at least one selected from the group consisting of fluorine, chlorine, and bromine; and europium.

17. A light source device, comprising:
the light emitting device according to claim 1, the light emitting device comprising:
a first light emitting device emitting light having a correlated color temperature in a range of 7000 K to 9200 K; and
a second light emitting device emitting light having a correlated color temperature in a range of 2600 K to 2900 K; wherein
a color of light emitted from the light source device is adjustable in a correlated color temperature range of 2600 K to 9200 K.

18. The light source device according to claim 17, wherein the light emitted from the light source device has a color deviation duv from the blackbody radiation locus in a range of −0.015 to −0.001 in a CIE 1931 chromaticity diagram.
